(19) United States
(12) Patent Application Publication
(10) Pub. No.: US 2006/0071231 A1
(43) Pub. Date: Apr. 6, 2006

(54) Optical film, backlight assembly having the same and display device having the same

(76) Inventors: Byung-Woong Han, Incheon Gwangyeock-si (KR); Kyu-Seok Kim, Yongin-si (KR); Young-Bee Chu, Suwon-si (KR); Sang-Hee Lee, Yongin-si (KR); Ju-Hyoun Kim, Suwon-si (KR); Sung-Min Kim, Yongin-si (KR)

Correspondence Address: CANTOR COLBURN, LLP, 55 GRIFFIN ROAD SOUTH, BLOOMFIELD, CT, 06002, US

(21) Appl. No.: 11/239,508

(22) Filed: Sep. 29, 2005

(30) Foreign Application Priority Data
Oct. 1, 2004 (KR) 2004-78310
Nov. 30, 2004 (KR) 2004-99383

(51) Int. Cl. H01L 33/00

(52) U.S. Cl. 257/103

(57) ABSTRACT

An optical film includes a base layer, a resin layer and a plurality of hollow particles. The resin layer is disposed on a surface of the base layer. The hollow particles are disposed in the resin layer. The hollow particles each have an epidermis that defines an inner space of a hollow particle. The hollow particles reflect or transmit light due to a refractive index difference between the epidermis and the inner space.

This application claims priority to Korean Patent Application No. 2004-78310 filed on Oct. 1, 2004 and Korean Patent Application No. 2004-99383 filed on Nov. 30, 2004, the contents of which are herein incorporated by reference in their entireties.

### BACKGROUND OF THE INVENTION

1. Field of the Invention

The present invention relates generally to an optical film, a backlight assembly having the optical film and a display apparatus having the optical film. More particularly, the present invention relates to an optical film having improved diffusivity and reflectivity, a backlight assembly having the optical film and a display apparatus having the optical film.

2. Description of the Related Art

In general, a liquid crystal display apparatus displays images using either an external light passing through a liquid crystal display panel or an internal light provided from a backlight assembly, such as a light source disposed under the liquid crystal display panel, since the liquid crystal display panel is not self-emissive.

The backlight assembly includes a lamp unit, a light guide plate, a reflecting plate (or reflecting sheet) and an optical sheet. The lamp unit generates light, and the light guide plate guides the light emitted from the lamp unit toward the liquid crystal display panel. The reflecting plate is disposed under the light guide plate and reflects light leaking from the light guide plate back toward the light guide plate. The optical sheet enhances a brightness of the light emitted from light guide plate.

FIGS. 1A-1C depict various conventional optical films. In particular, FIG. 1A is a cross-sectional view of a diffusely reflecting sheet, FIG. 1B is a cross-sectional view of a laminated reflecting sheet, and FIG. 1C is a cross-sectional view of a metal deposited film.

Referring to FIG. 1A, the diffusely reflecting sheet includes polyethylene terephthalate (PET) 10 in which an air space 12, for example, an air bubble, is formed. The diffusely reflecting sheet has a first protecting PET 14 disposed on a first surface of the PET 10 and a second protecting PET 16 disposed on a second 10 surface of the PET 10. The diffusely reflecting sheet diffusely reflects light using a refractive index difference between the PET 10 and the air space 12. The diffusely reflecting sheet has advantageous characteristics such a slow manufacturing cost and high diffusivity of the light, but also has disadvantageous characteristics such as low reflectivity of the light and relatively large thickness.

Referring to FIG. 1B, the laminated reflecting sheet includes a plurality of first thin films 20, 24 and 28 having an isotropic material and a plurality of second thin films 22 and 26 having a refractive index different from the first thin films 20, 24 and 28. The second thin films 22 and 26 are disposed between the first thin films 20, 24 and 28, respectively. As a result, the laminated reflecting sheet regularly reflects 20 the light. The laminated reflecting sheet has some advantages such as high reflectance of the light and relatively small thickness, but the laminated reflecting sheet has low diffusivity of the light.

Referring to FIG. 1C, the metal deposited film has a PET layer 30, a silver deposited layer 32 and a passivation layer 34. The silver deposited layer 32 is formed on a surface of the PET layer 30, and the passivation layer 34 is formed on the silver deposited layer 32. Disadvantages of the metal deposited film include low reflectance of the light and low diffusivity of the light.

Therefore, a need exists for an optical film with improved diffusivity and reflectivity.

### SUMMARY OF THE INVENTION

The present invention provides an optical film having a thinner thickness and improved diffusivity and reflectivity.

The present invention also provides a backlight assembly having the above optical film.

The present invention also provides a display apparatus having the above optical film.

In one aspect of the present invention, an optical film includes a base layer, a resin layer and a plurality of hollow particles. The resin layer is disposed on the base layer. The hollow particles are disposed in the resin layer.

In another aspect of the present invention, a backlight assembly includes a lamp and an optical film. The lamp generates light, and the optical film reflects the light so that an optical characteristic of the light is improved. The optical film includes a base layer, a resin layer disposed on the base layer, and a plurality of hollow particles disposed in the resin layer.

In still another aspect of the present invention, a display apparatus includes a light source, a liquid crystal display panel and an optical film. The light source generates light. The liquid crystal display panel displays images using a potential difference that is applied to a liquid crystal layer. The optical film diffusely reflects the light from the lamp toward the liquid crystal display panel. The optical film includes a base layer, a resin layer, and a plurality of hollow particles disposed in the resin layer.

In further still another aspect of the present invention, the display apparatus includes at least two display panels and at least one backlight assembly. The display panels display an images. The backlight assembly supplies light to the display panels and includes a reflecting sheet to reflect the light. The reflecting sheet includes a base layer, a resin layer disposed on the base layer, and a plurality of hollow particles disposed in the resin layer.

According to the above, since the hollow particles are coated on the base layer of the optical film, diffusivity and reflectivity of the optical film may be improved.

### BRIEF DESCRIPTION OF THE DRAWINGS

The above and other advantages of the present invention will become readily apparent by reference to the following detailed description when considered in conjunction with the accompanying drawings wherein:

FIGS. 1A to 1C are cross-sectional views of general optical films;

FIG. 2 is a cross-sectional view of an optical film according to an exemplary embodiment of the present invention;

FIG. 3 is a cross-sectional view of a hollow particle shown in the optical film of FIG. 2;

FIG. 4 is a view illustrating a size, a reflection processing and a transmission processing of the hollow particle shown in FIG. 2;

FIGS. 5A to 5C are graphs illustrating a reflection viewing angle characteristic of optical films;

FIGS. 6A to 6C are graphs illustrating a reflection angle characteristic of optical films;

FIGS. 7A to 7C are graphs illustrating a reflection viewing angle characteristic of optical films in a vertical direction;

FIGS. 8A to 8C are graphs illustrating a reflection angle characteristic of optical films in a horizontal direction;

FIG. 9A is a view illustrating a method of measuring brightness;

FIG. 9B is a view showing a test point mapped on a test substrate;

FIG. 10 is an exploded perspective view of a backlight assembly according to an exemplary embodiment of the present invention;

FIG. 11 is a view illustrating a light guiding process of the light guide plate shown in FIG. 10;

FIG. 12 is an exploded perspective view of a backlight assembly according to another exemplary embodiment of the present invention;

FIG. 13 is an exploded perspective view of a liquid crystal display apparatus according to an exemplary embodiment of the present invention;

FIG. 14 is an exploded perspective view of a liquid crystal display apparatus according to another exemplary embodiment of the present invention;

FIG. 15 is an exploded perspective view of a liquid crystal display apparatus according to another exemplary embodiment of the present invention;

FIG. 16 is an exploded perspective view of a liquid crystal display apparatus according to still another exemplary embodiment of the present invention;

FIG. 17A is an exploded perspective view of a liquid crystal display apparatus according to further another exemplary embodiment of the present invention;

FIG. 17B is a partially enlarged view of a reflecting sheet in FIG. 17A;

FIG. 18 is a combined perspective view of a liquid crystal display apparatus in FIG. 17;

FIG. 19 is a cross-sectional view taken along line I-I′ in FIG. 18; and

FIG. 20 is an enlarged view of portion “A” of FIG. 19.

### DETAILED DESCRIPTION OF THE INVENTION

It will be understood that when an element or layer is referred to as being “on”, “connected to” or “coupled to” another element or layer, it can be directly on, connected with, or coupled to the other element or layer, or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the Figures. It will be understood that the spatially relative terms are intended to encompass different orientations of the device in use or operation in addition to the orientation depicted in the Figures. For example, if the device in the Figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

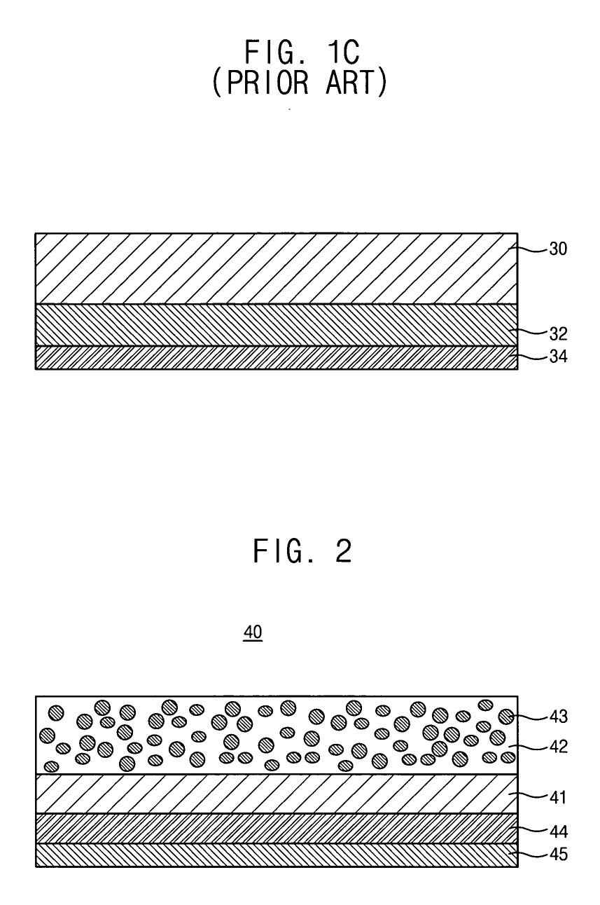

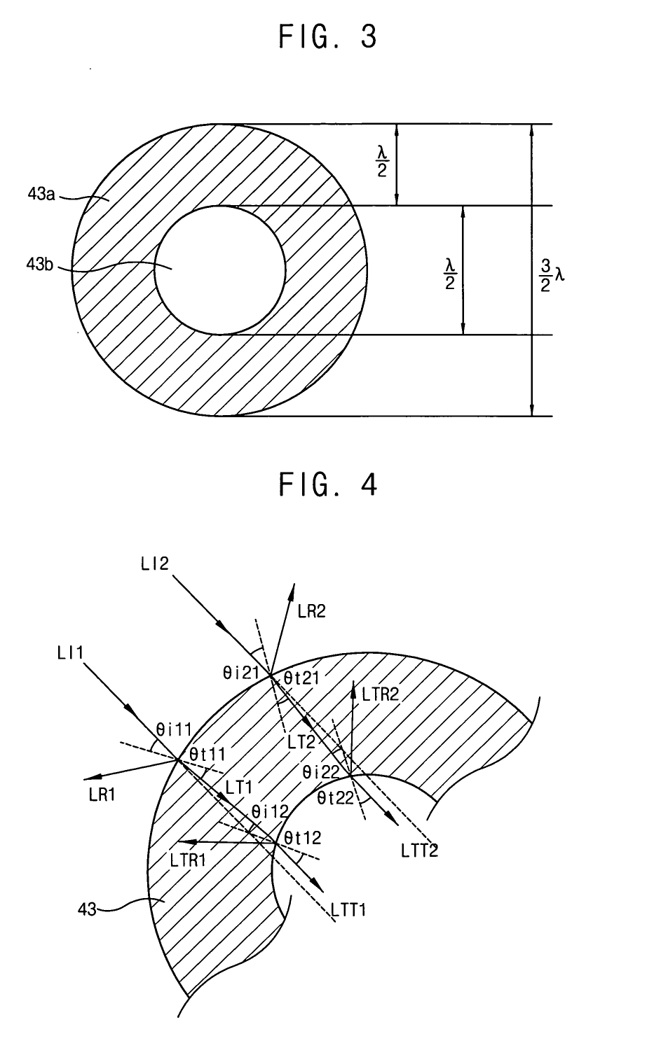

FIG. 2 is a cross-sectional view of an optical film according to an exemplary embodiment of the present invention. FIG. 3 is a cross-sectional view of a hollow particle of the optical film shown in FIG. 2.

Referring to FIGS. 2 and 3, an optical film 40 includes a base layer 41, a resin layer 42, a plurality of hollow particles 43, a metal layer 44 and a passivation layer 45. The resin layer 42 is formed on the base layer 41, and the hollow particles 43 are added into the resin layer 42. The metal layer 44 is formed under the base layer 41, and the passivation layer 45 is formed under the metal layer 44.

The base layer 41 includes a polyethylene terephthalate material. The resin layer 42 includes a polyurethane material.

The hollow particles 43 may have a rounded shape, a ball shape or the like. The hollow particles 43 diffusely reflect light supplied from an exterior source through an outer surface of the hollow particles 43. The outer surface of the hollow particles 43 may have various cross-sectional profiles, for example, such as a circular shape, elliptical shape, etc. A diameter of the hollow particles 43 is determined in consideration of a wavelength of the light supplied to the hollow particles 43. Particularly, when a red light is supplied to the hollow particles 43, the hollow particles 43 have a diameter corresponding to a wavelength of about 650 nm so as to effectively reflect the red light. Also, when a green light is supplied to the hollow particles 43, the hollow particles 43 have a diameter corresponding to a wavelength of about 550 nm so as to effectively reflect the green light. In addition, when a blue light is supplied to the hollow particles 43, the hollow particles 43 have a diameter corresponding to a wavelength of about 450 nm so as to effectively reflect the blue light.

The hollow particles 43 may have a diameter of about 2.9λ/2 to about 3.1λ/2. In an exemplary embodiment, the hollow particles 43 have a diameter of about 3λ/2. The ‘λ’ indicates a wavelength of a standard light that is the green light having the wavelength of about 550 nm. For example, when the red light has the wavelength of about 650 nm, the hollow particles 43 have a diameter of about 97.5 angstroms. When the green light has the wavelength of about 550 nm, the hollow particles 43 have a diameter of about 82.5 angstroms. When the blue light has the wavelength of about 450 nm, the hollow particles 43 have a diameter of about 67.5 angstroms.

As shown in FIG. 3, an epidermis 43a of the hollow particles 43 has a thickness of about 0.49% to about 0.51λ. In an exemplary embodiment, the epidermis 43a has a thickness of about 22.0 angstroms to about 33.1 angstroms.

The hollow particles 43 include a first resin and reflect the light supplied to the hollow particles 43 using a refractive index difference between the first resin and an inner space 43b of the hollow particles 43. The resin layer 42 includes a second resin having a refractive index different from the first resin. The resin layer 42 reflects the light supplied to the resin layer 42 using a refractive index difference between the first resin and the second resin. The second resin includes a transparent material.

The hollow particles 43 transmit the light supplied to the hollow particles 43 due to a refractive index difference between the first resin and the inner space 43b.

The metal layer 44 includes a material having a high reflectance, for example, silver (Ag) or aluminum (Al).

Hereinafter, a transmitting operation and a reflecting operation of the hollow particles 43 will be described below with reference to FIG. 4.

FIG. 4 is a view illustrating a reflecting operation and a transmitting operation of the hollow particles 43 shown in FIG. 2.

Referring to FIG. 4, a portion LR1 of a first light LI1 supplied to the outer surface of the hollow particles 43 is reflected by the outer surface at an angle same as a first incident angle θi11, and a remaining portion LT1 of the first light LI1 passes through the outer surface at a first transmitting angle θt11 which is, for example, less than the first incident angle θi11.

A portion LTR1 of light LT1 that transmits through the outer surface is reflected by the inner surface of the hollow particles 43 at an angle same as a second incident angle θi12, and a remaining portion LTT1 of the light LT1 passes through the inner surface at a second transmitting angle θt12 which is, for example, greater than the second incident angle θi12.

On the other hand, a portion LR2 of a second light L12 supplied to the outer surface of the hollow particles 43 is reflected by the outer surface at an angle same as a third incident angle θi21, and a remaining portion LT2 of the second light LI2 passes through the outer surface at a third transmitting angle θt21 which is, for example, less than the third incident angle θi21.

A portion LTR2 of light LT2 that transmits through the outer surface is reflected by the inner surface of the hollow particles 43 at an angle same as a fourth incident angle θi22, and a remaining portion LTT2 of the light LT2 passes through the inner surface at a fourth transmitting angle θt22 which is, for example, greater than the fourth incident angle θi22.

As described above, since the outer surface of the hollow particles 43 has a rounded shape or the like, the hollow particles 43 may diffuse and reflect the light supplied to the hollow particles 43 in more effective way.

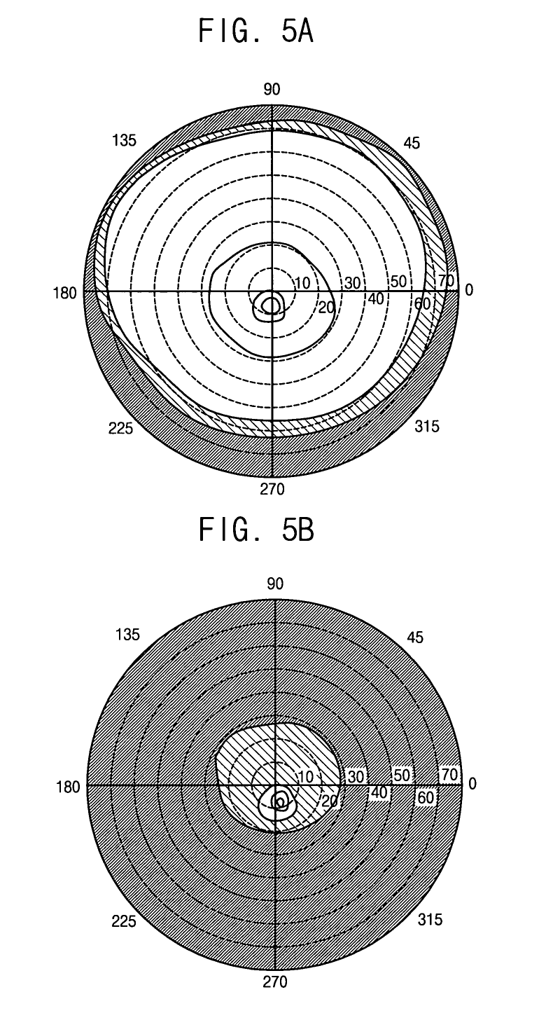

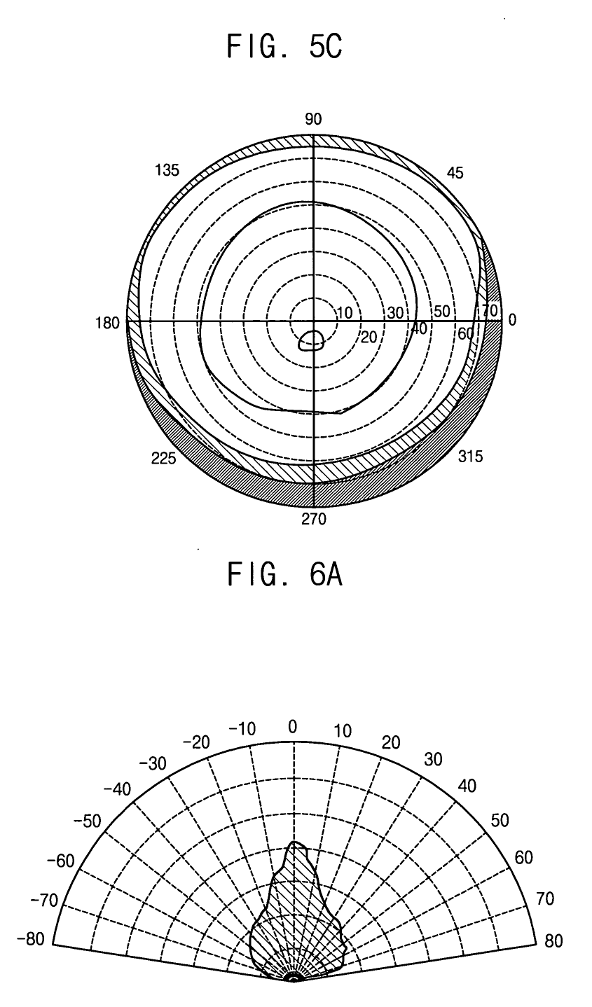

FIGS. 5A to 5C are graphs illustrating a reflection viewing angle characteristic of optical films. Particularly, FIG. 5A represents a graph showing a reflection viewing angle characteristic of a first diffusely reflecting sheet including an E60L (trade name produced by Toray Company in Japan), FIG. 5B represents a graph showing a reflection viewing angle characteristic of a second diffusely reflecting sheet including a MCPET (trade name produced by Idemitsu Company in Japan), and FIG. 5C represents a graph showing a reflection viewing angle characteristic of a reflecting sheet according to an embodiment of the present invention. The reflection viewing angle characteristic of the optical films was measured using an Ez contrast 160R apparatus (trade name manufactured by ELDIM Company in France) while the light was supplied to the optical films at an angle of about ten degrees with respect to a front of the optical films. In FIGS. 5A to 5C, as a hatched area becomes darker, an amount of a reflection light decreases, and as the distance away from the hatched area increases, the amount of the reflection light increases.

Referring to FIGS. 5A to 5C, the first diffusely reflecting sheet may enhance a viewing angle of the reflection light better than that of the second diffusely reflecting sheet. However, the reflecting sheet according to an embodiment of the present invention may enhance the viewing angle of the reflection light even better than the first diffusely reflecting sheet.

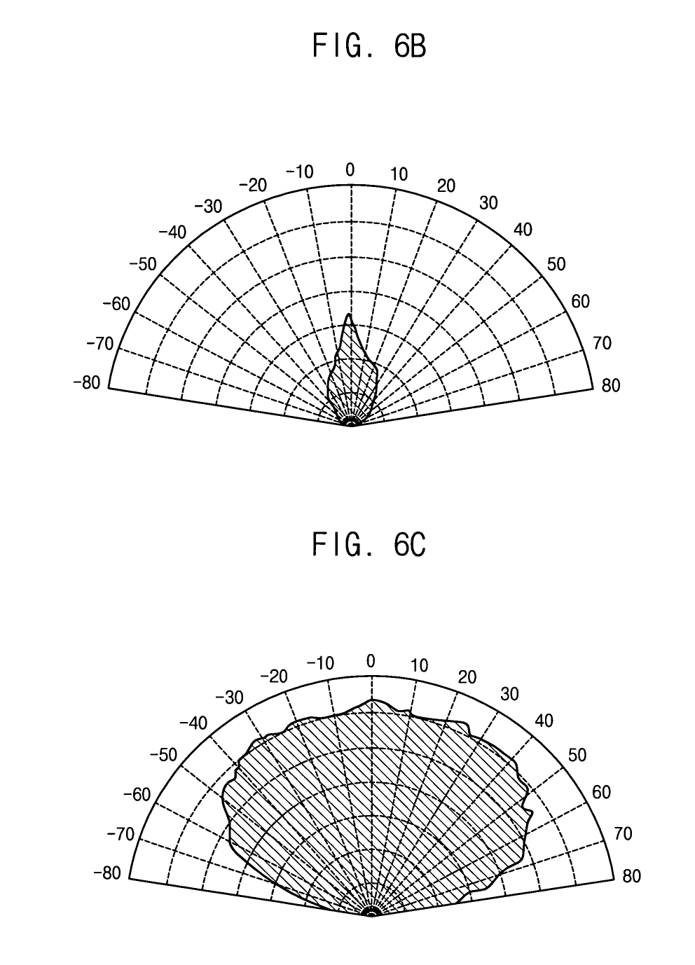

FIGS. 6A to 6C are graphs illustrating a reflection angle characteristic of optical films. In particular, FIG. 6A represents a graph showing a reflection angle characteristic of a first diffusely reflecting sheet including the E60L, FIG. 6B represents a graph showing a reflection angle characteristic of a second diffusely reflecting sheet including the MCPET, and FIG. 6C represents a graph showing a reflection angle characteristic of a reflecting sheet according to an embodiment of the present invention.

Referring to FIGS. 6A to 6C, the first diffusely reflecting sheet of FIG. 6A may enhance the reflection angle better than the second diffusely reflecting sheet of FIG. 6B. However, the reflecting sheet according to an embodiment of the present invention (FIG. 6C) may enhance the reflection angle even better than the first diffusely reflecting sheet.

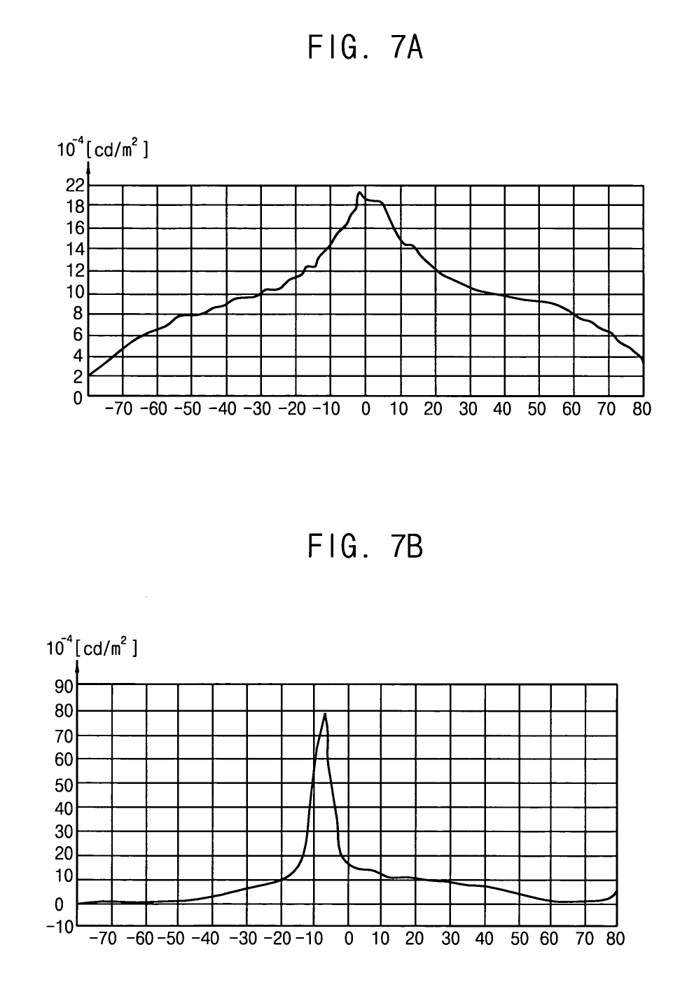

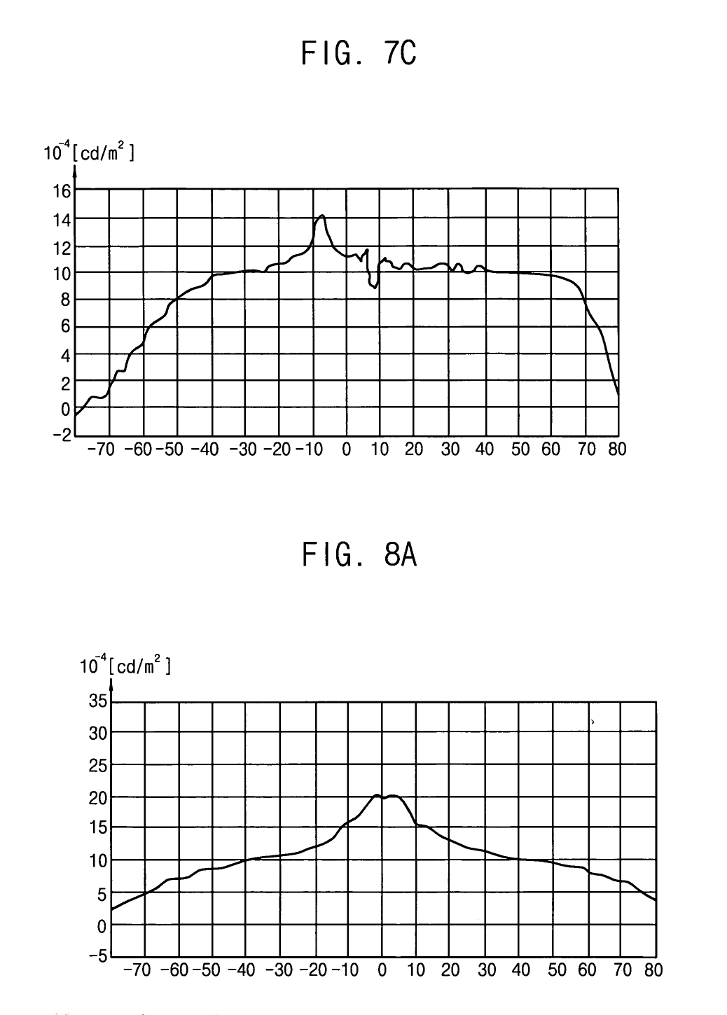

FIGS. 7A to 7C are graphs illustrating a reflection viewing angle characteristic of optical films in a vertical direction. Particularly, FIG. 7A represents a graph showing a reflection viewing angle characteristic of a first diffusely reflecting sheet including the E60L in a vertical direction, FIG. 7B represents a graph showing a reflection viewing angle characteristic of a second diffusely reflecting sheet including the MCPET in the vertical direction, and FIG. 7C represents a graph showing a reflection viewing angle characteristic of a reflecting sheet according to an embodiment of the present invention in the vertical direction.

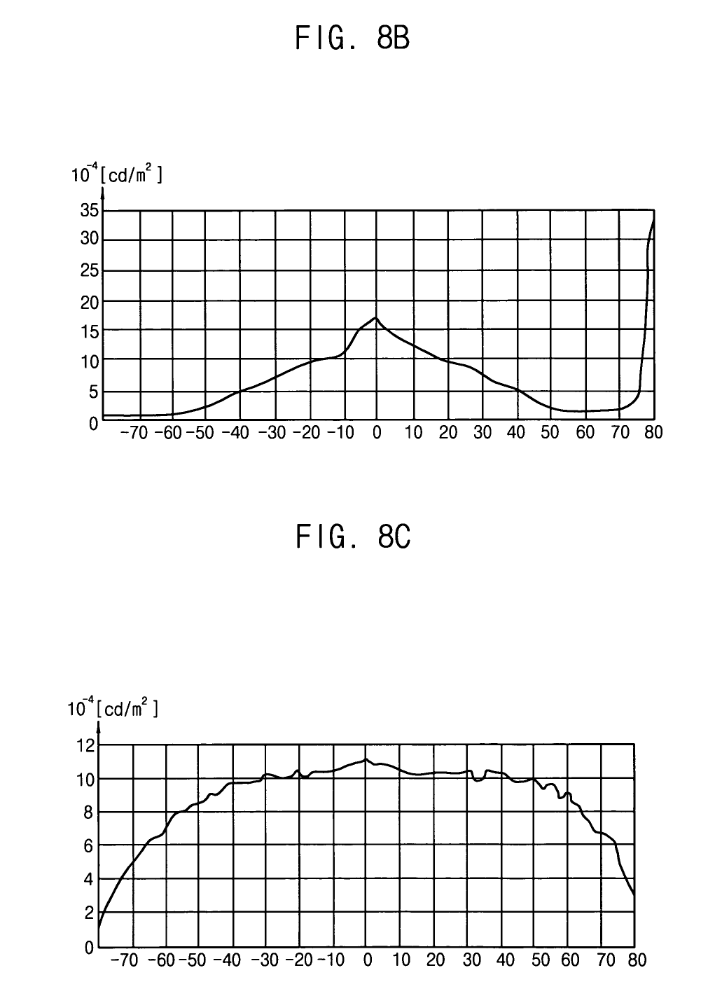

FIGS. 8A to 8C are graphs illustrating a reflection angle characteristic of optical sheets in a horizontal direction. In particular, FIG. 8A represents a graph showing a reflection angle characteristic of a first diffusely reflecting sheet including the E60L in a horizontal direction, FIG. 8B represents a graph showing a reflection angle characteristic of a second diffusely reflecting sheet including the MCPET in the horizontal direction, and FIG. 8C represents a graph showing a reflection angle characteristic of a reflecting sheet according to an embodiment of the present invention in the horizontal direction.

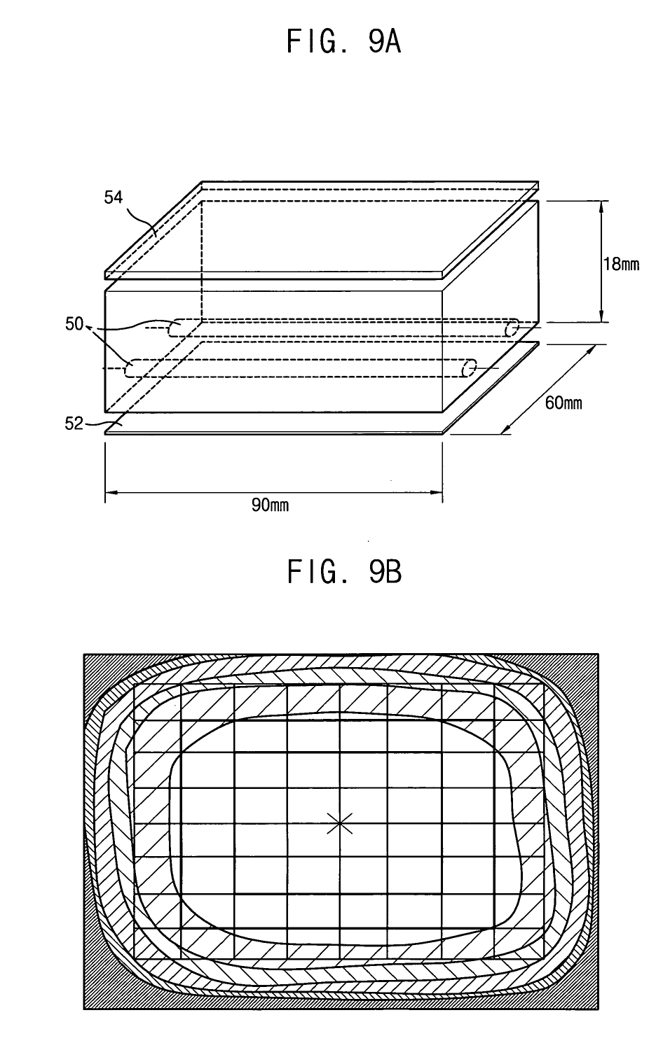

FIG. 9A is a view illustrating a method of measuring brightness. FIG. 9B is a view showing a test point mapped on a test substrate after one hour. FIG. 9B represents eighty-one mapped test points on the test substrate in nine by nine matrix shape. The brightness in FIG. 9A is measured by a testing system of a RISA manufactured by HI-LAND Company in Japan. In FIG. 9B, as a hatched area becomes darker, an amount of a reflection light decreases, and as a distance away from the hatched area increases, the amount of the reflection light increases.

Referring to FIGS. 9A and 9B, a reflecting sheet 52 is disposed under a plurality of lamps 50, and a diffusing sheet 54 is disposed over the lamps 50. Each of the lamps 50 includes a cold cathode fluorescent tube having a diameter of about 1.8 millimeters and a length of about 91 millimeters. Also, the diffusing sheet 54 has a thickness of about two millimeters, and the reflecting sheet according to the present invention is different from a conventional reflecting sheet employed in a conventional liquid crystal display device.

Table 1 represents brightness measured at the mapped test points of the test substrate one hour after a voltage is applied to lamps.

TABLE 1

| | | Bright- | Average | Average | |
|---|---|---|---|---|---|
| | Thick- | ness | brightness | brightness | Maximum |
| | ness | (49/81) | (49/81) | (25/81) | brightness |
| | (μm) | [%] | [mcd] | [mcd] | [mcd] |
| Comparative | 975 | 99.7 | 2452 | 2800 | 3034 |
| Example 1 | | | | | |
| Comparative | 188 | 96.8 | 2416 | 2760 | 2989 |
| Example 2 | | | | | |
| Comparative | 65 | 89.6 | 2235 | 2516 | 2815 |
| Example 3 | | | | | |
| Example 1 | 65 | 100 | 2495 | 2820 | 3067 |

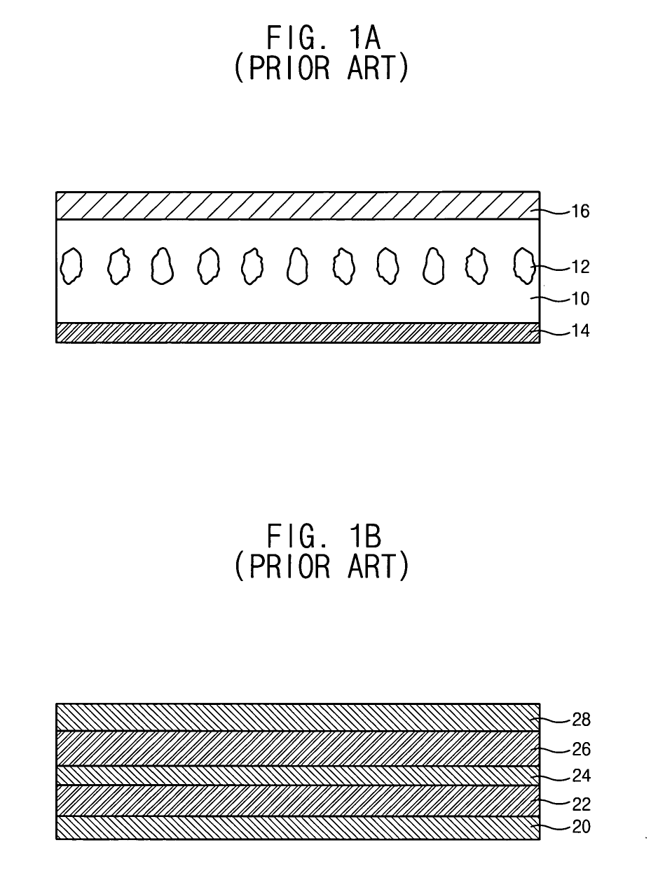

In Table 1, Comparative Example 1 and Comparative Example 2 indicate the first diffusely reflecting sheet and the second diffusely reflecting sheet are substantially the same as the diffusely reflecting sheet of FIG. 1A, respectively. Comparative Example 3 indicates the laminated reflecting sheet of FIG. 1B and Example 1 indicates the reflecting sheet according to one embodiment of the present invention.

As shown in Table 1, the first diffusely reflecting sheet, the second diffusely reflecting sheet and the laminated reflecting sheet have a thickness of 975 micrometers, 188 micrometers and 65 micrometers, respectively. On the contrary, the reflecting sheet according to one embodiment of the present embodiment has a thickness of 65 micrometers. Therefore, the reflecting sheet has a thickness that is thinner than those of the first and second diffusely reflecting sheets.

Further, Table 1 represents brightness measured in forty-nine mapped test points of the eighty-one mapped test points. When assuming that the brightness measured in Example 1 is 100%, the brightness in Comparative Example 1, Comparative Example 2 and Comparative Example 3 have been represented by 99.2%, 96.8% and 89.6%, respectively. That is, the brightness measured in Example 1 is greater than the brightness in Comparative Example 1, Comparative Example 2 and Comparative Example 3.

Furthermore, Table 1 represents average brightness measured in forty-five mapped test points of the eighty-one mapped test points. The average brightness in Comparative Examples 1, 2 and 3 have been represented by 2452mcd, 2416mcd and 2235mcd, respectively. On the contrary, the average brightness in Example 1 has been represented by 2495mcd. That is, the average brightness measured in Example 1 is greater than the average brightness in Comparative Examples 1, 2 and 3.

Furthermore, Table 1 represents average brightness measured in twenty-five mapped test points of the eighty-one test points. The average brightness in Comparative Examples 1, 2 and 3 have been represented by 2800mcd, 2760mcd and 2516mcd, respectively. On the contrary, the average brightness in Example 1 has been represented by 2820mcd. That is, the average brightness measured in Example 1 is greater than the average brightness in Comparative Examples 1, 2 and 3.

The maximum brightness in Comparative Examples 1, 2 and 3 have been represented by 3040mcd, 2989mcd and 2815mcd, respectively. On the contrary, the maximum brightness in Example 1 has been represented by 3067mcd. That is, the maximum brightness measured in Example 1 is greater than the maximum brightness in Comparative Examples 1, 2 and 3.

Hereinafter, exemplary embodiments of backlight assembly having the reflecting sheet according to the present invention will be described below with reference to the figures.

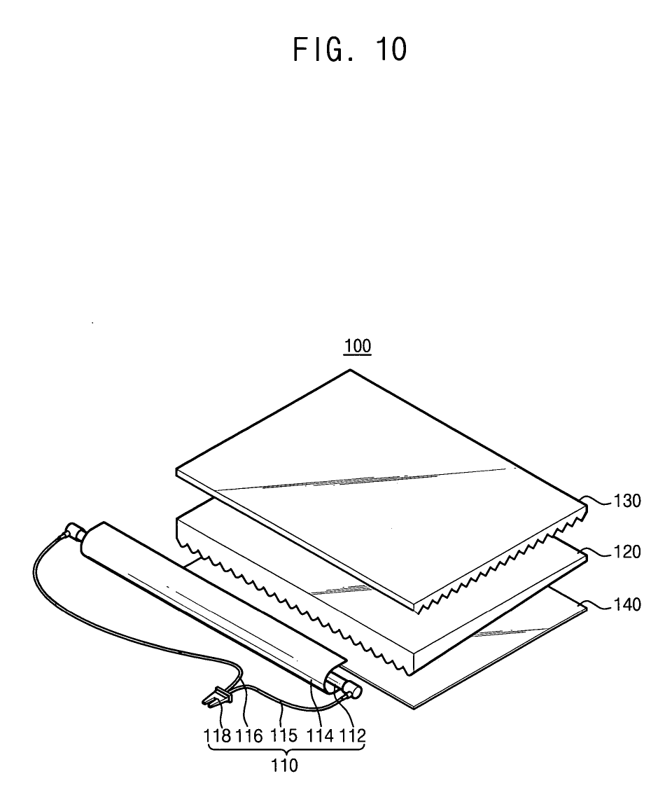

FIG. 10 is an exploded perspective view showing a backlight assembly according to an exemplary embodiment of the present invention.

Referring to FIG. 10, a backlight assembly 100 includes a light generating part 110, a light guiding plate 120, a reversed prism film 130 and a reflecting sheet 140.

The light generating part 110 has a lamp 112, a lamp cover 114, a first wire 115, a second wire 116 and a connector 118. The lamp 112 generates light in response to a power voltage that is applied to the lamp 112 via the connector 118, the first wire 115 and the second wire 116. The lamp cover 114 partially covers the lamp 112 and a portion of the reflecting sheet 140. The reflecting sheet 140 has substantially the same structure as the optical film 40 of FIGS. 2 and 3.

The light guide plate 120 is disposed between the reversed prism film 130 and the reflecting sheet 140. A plurality of prisms are formed on a surface of the light guide plate 120 facing the reflecting sheet 140 and extend in a direction substantially perpendicular to a longitudinal direction of the lamp 112. The prisms of the light guide plate 120 guide the light from the light generating part 110 and the reflecting sheet 140 to the reversed prism film 130.

In cross-sectional views of the prisms of the light guiding plate 120, each of pitches of the prisms has a round shape, a parabola shape or the like. In an exemplary embodiment, curvatures of the prisms gradually decrease in proportion to a distance between the lamp 112 and the pitches of the prisms.

The reversed prism film 130 is disposed over an emitting surface of the light guide plate 120. The revered prism film 130 diffuses and collects the light guided by the light guide plate 120 so as to control a brightness characteristic of the light. The reversed prism film 130 has prisms each extending in a direction substantially parallel with the longitudinal direction of the lamp 112.

The reflecting sheet 140 is disposed under the light guide plate 120 and reflects light leaked from the light guide plate 120. In an exemplary embodiment, the backlight assembly 100 includes a flexible type reflecting sheet; however, it will be understood that a rigid type reflecting plate may be used for the backlight assembly 100 instead of the flexible type reflecting sheet.

As described above, in the backlight assembly 100 employing the light guide plate 120, the light guide plate 120 has the prisms formed on the rear surface of the light guide plate 120 facing the reflecting sheet 140. The prisms are extended to the direction substantially perpendicular to the longitudinal direction of the lamp 112, and the pitches of the prisms have a round shape in an area adjacent to the lamp. Therefore, the backlight assembly may prevent the appearance of a bright line at corners of a light incident portion of the light guide plate 120.

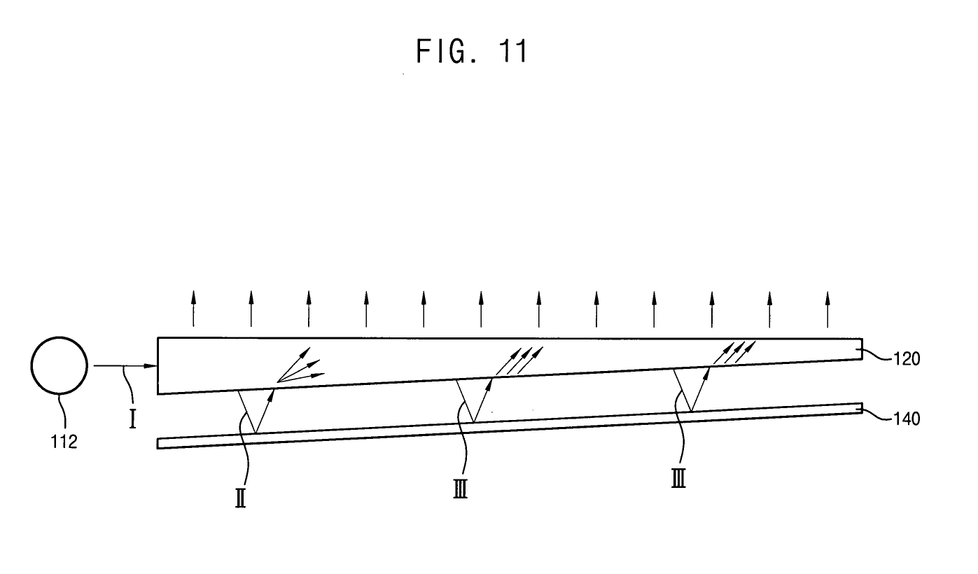

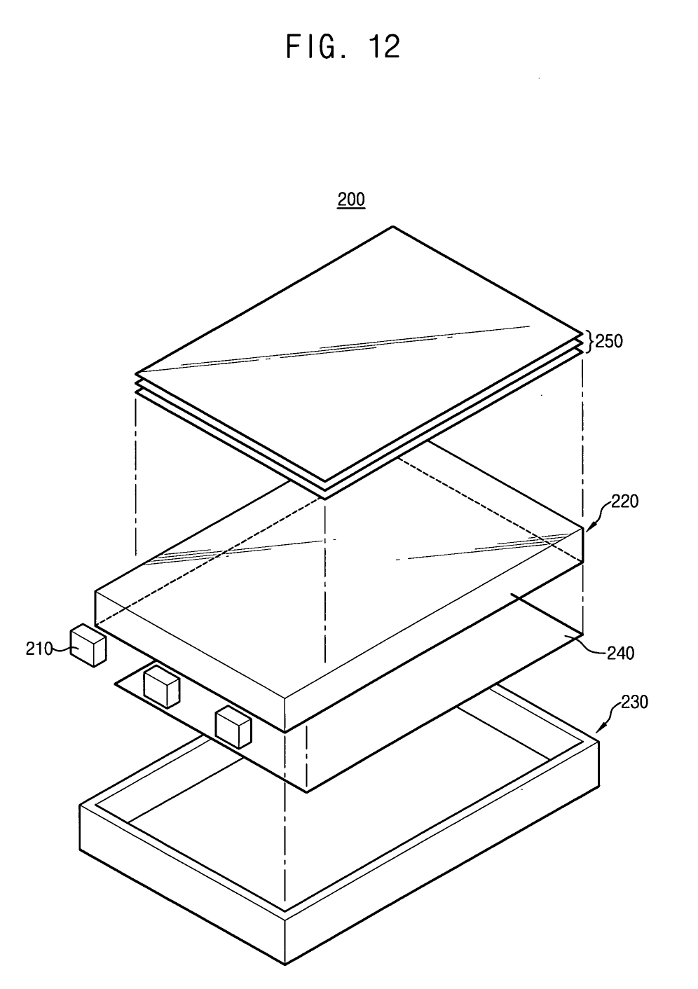

FIG. 11 is a view illustrating a light guiding process of the light guide plate shown in FIG. 10.

Referring to FIGS. 10 and 11, a first light (I) from the lamp 112 is incident into an incident surface of the light guide plate 120 and guided by the light guide plate 120. As a result, the first light (I) is emitted from an emitting surface of the light guide plate 120 via a first light guiding process of the light guide plate 120.

A portion of the first light (I) is leaked from a reflecting surface of the light guide plate 120. A second light (II) that is a portion of the light leaked from the reflecting surface is reflected by the reflecting sheet 140 and diffusely passes through the light guide plate 120. As a result, the second light (II) is emitted from the emitting surface of the light guide plate 120 via a second light guiding process of the light guide plate 120. Also, a third light (III) that represents a remaining portion of the light leaked by the reflecting surface is reflected from the reflecting sheet 140 and diffusely passes through the light guide plate 120. As a result, the third light (III) is emitted from the emitting surface via a third light guiding process of the light guide plate 120. The third light (III) is more diffused by the light guide plate 120 than the second light (II).

FIG. 12 is an exploded perspective view showing a backlight assembly according to another exemplary embodiment of the present invention.

Referring to FIG. 12, a backlight assembly 200 includes a light source 210, a light guide plate 220, a receiving container 230 and a reflecting sheet 240. The light source 210 generates light, and the light guide plate 220 receives the light from the light source 210 and varies a path of the light. The receiving container 230 receives the light source 210 and the light guide plate 220. The reflecting sheet 240 reflects light leaked from light guide plate 220. The reflecting sheet 240 has substantially the same structure as the optical film 40 of FIGS. 2 and 3 and includes the hollow particles 43 (refer to FIGS. 2 and 3) so as to improve diffusion and reflection characteristics.

The light source 210 includes a plurality of light emitting diodes (LED) having a point shape, and is disposed adjacent to a side surface of the light guide plate 220.

The light guide plate 220 has an incident surface, an emitting surface and a reflection surface. The incident surface receives the light from the light source 210.

The emitting surface is extended from a first end portion of the incident surface in a direction substantially perpendicular to the incident surface. The reflection surface is extended from a second end portion of the incident surface in a direction substantially in parallel to the emitting surface.

The reflecting sheet 240 is disposed between the reflection surface of the light guide plate 220 and the receiving container 230 and reflects light leaked from the reflection surface toward the light guide plate 220. The reflecting sheet 240 has a size corresponding to the reflection surface of the light guide plate 220.

The backlight assembly 200 further includes a plurality of optical sheets 250 disposed over the emitting surface of the light guide plate 220. The optical sheets 250 improve an optical characteristic of the light emitted from emitting surface. The optical sheets 250 include a diffusing sheet and at least one collecting sheet.

Therefore, the optical sheets may improve brightness and a viewing angle of the light emitted from the emitting surface.

Hereinafter, various liquid crystal display apparatuses having the optical film according to the present invention will be described below with reference to Figures.

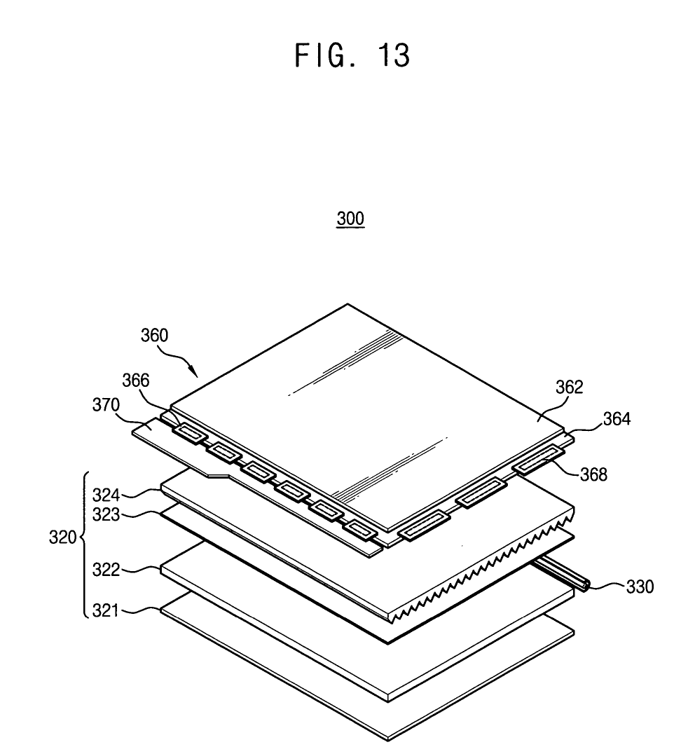

FIG. 13 is an exploded perspective view showing a liquid crystal display apparatus according to an exemplary embodiment of the present invention.

Referring to FIG. 13, a liquid crystal display apparatus 300 includes a light control part 320, a polarizing plate (not shown) and a liquid crystal panel 360. The light control part 320 controls light from a lamp 330, and the polarizing plate polarizes light passing through the light control part 320. The liquid crystal panel 360 includes a color filter substrate 362, a thin film transistor substrate 364, a source printed circuit board 370, a source driver 366 and a gate driver 368. The liquid crystal panel 360 displays an image using the light polarized by the polarizing plate.

The lamp 330 may include various light sources such as a cold cathode fluorescent, a light emitting diode, an external electrode fluorescent, etc.

The light control part 320 includes a plurality of sheets or a plurality of plates so as to improve brightness and a viewing angle of the light from the lamp 330 and provide the liquid crystal panel 360 with the light having an improved brightness and an improved viewing angle.

The lamp 330 is disposed adjacent to a side surface of a light guide plate 322. The light from the lamp 330 is supplied to the light guide plate 322 and reflected from a reflection surface of the light guide plate 322 or a reflecting sheet 321 disposed under the light guide plate 322. The reflected light is emitted from the light guide plate 322 and supplied to a diffusing film 323. The diffusing film 323 diffuses the reflected light and provides a reversed prism film 324 with the diffused light. The reversed prism film 324 collects the diffused light from the diffusing film 323 and provides the collected light to the liquid crystal panel 360. The reflecting sheet 321 has substantially the same structure as the optical film 40 of FIGS. 2 and 3 and includes the hollow particles 43 (refer to FIGS. 2 and 3) so as to improve a diffusion characteristic and a reflection characteristic of the reflecting sheet 321.

The reversed prism film 324 includes a plurality of prisms that is formed on a surface facing the diffusing film 323, and the light guide plate 322 includes a plurality of prisms that are formed on the reflection surface. The prisms of the reversed prism film 324 are extended in a first direction, and the prisms (refer to FIG. 10) of the light guide plate 322 are extended in a second direction substantially perpendicular to the first direction. Thus, the prisms of the reversed prism film 324 traverse the prisms of the light guide plate 322.

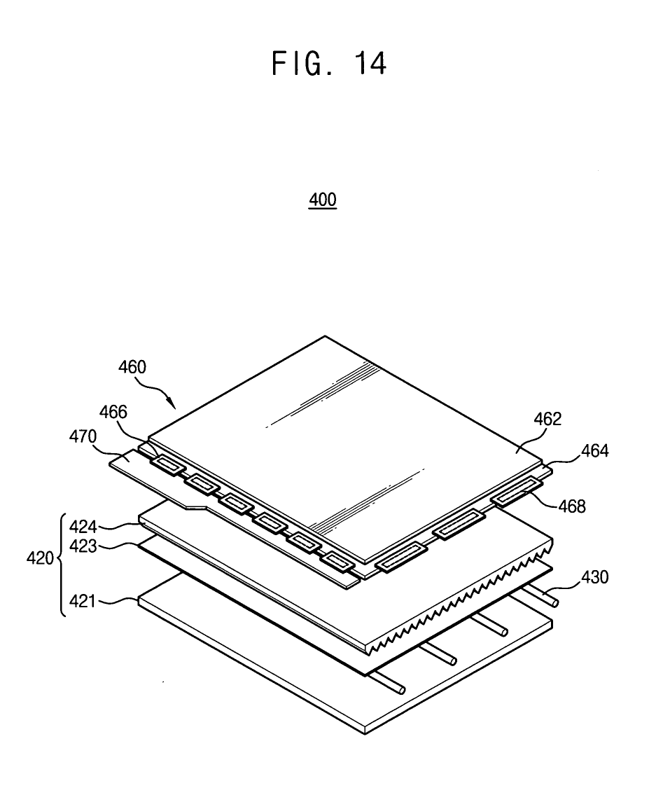

FIG. 14 is an exploded perspective view showing a liquid crystal display apparatus according to another exemplary embodiment of the present invention.

Referring to FIG. 14, a liquid crystal display apparatus 400 includes a light control part 420, a polarizing plate (not shown) and a liquid crystal panel 460. The light control part 420 controls light from a plurality of lamps 430, and the polarizing plate polarizes light passing through the light controlling part 420. The liquid crystal panel 460 includes a color filter substrate 462, a thin film transistor substrate 464, a source printed circuit board 470, a source driver 466 and a gate driver 468. The liquid crystal panel 460 displays an image using light polarized by the polarizing plate.

Each of the lamps 430 may include a cold cathode fluorescent, a light emitting diode or an external electrode fluorescent.

The light controlling part 420 includes a plurality of sheets or a plurality of plates so as to improve brightness and a viewing angle of the light from the lamps 430 and provide the light having an improved brightness and an improved viewing angle to the liquid crystal panel 460.

The lamps 430 are disposed under the liquid crystal panel 460 and substantially in parallel with each other. The light from the lamps 430 is directly supplied to a diffusing film 423, or the light from the lamps 430 is supplied to the diffusing film 423 after being reflected by a reflecting sheet 421 disposed under the lamps 430. The diffusing film 423 diffuses the light supplied to the diffusing film 423, and the light diffused by the diffusing film 423 is supplied to a reversed prism film 424. The reversed prism film 424 collects the light diffused by the diffusing film 423. The reflecting sheet 421 has substantially the same structure as the optical film 40 of FIGS. 2 and 3 and includes the hollow particles 43 (refer to FIGS. 2 and 3) so as to improve a diffusion characteristic and a reflection characteristic of the reflecting sheet 421.

The reversed prism film 424 includes a plurality of prisms that are formed on a surface facing the diffusing film 423. The prisms of the reversed prism film 424 are extended in a first direction substantially parallel with a longitudinal direction of the lamps 430.

Also, a light intensity of a first area of the reversed prism film 424 that corresponds to the lamps 430 is greater than a light intensity of a second area of the reversed prism film 424 that is between the lamps 430. In this embodiment, a tilt angle of the prisms of the reversed prism film 424 is varied in accordance with a position of the lamps 430, so that brightness uniformity of the light from the reversed prism film 424 is improved. For example, the prisms having relatively large tilt angles may be formed in the first area of the reversed prism film 424, and the prisms having relatively small tilt angles may be formed in the second area of the reversed film 424.

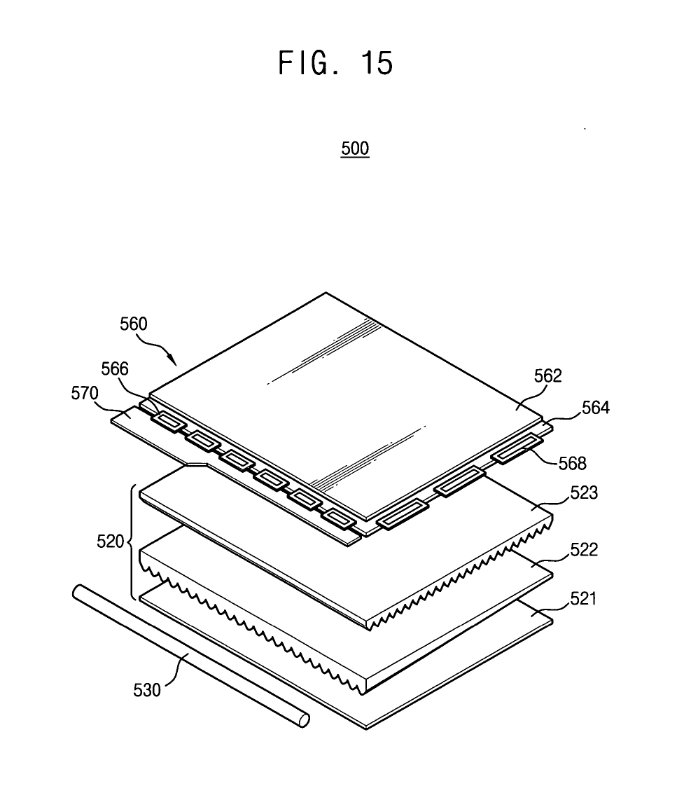

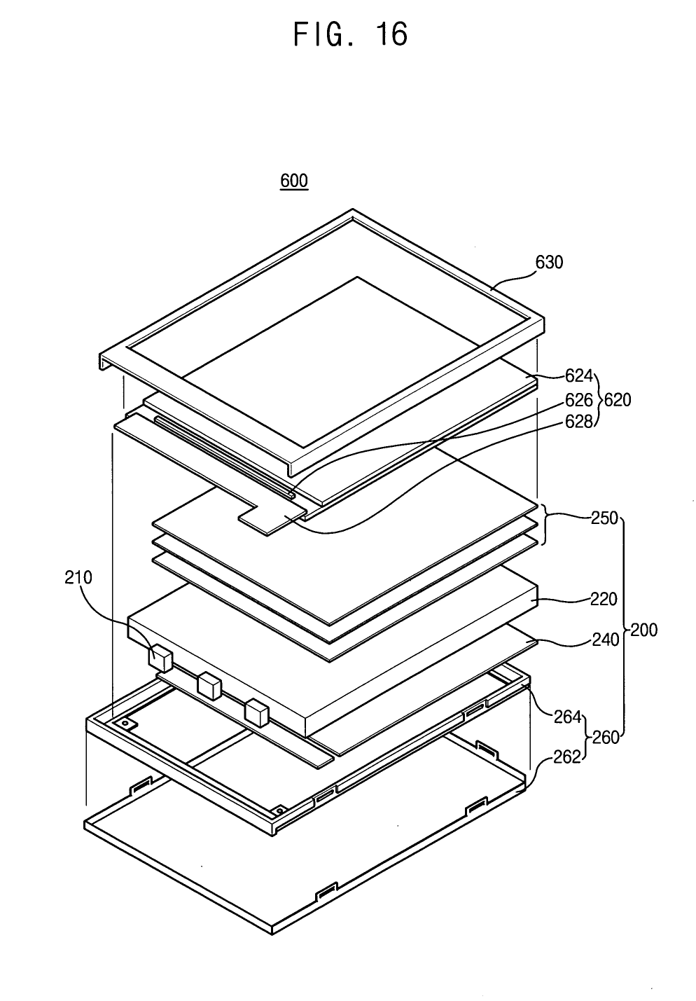

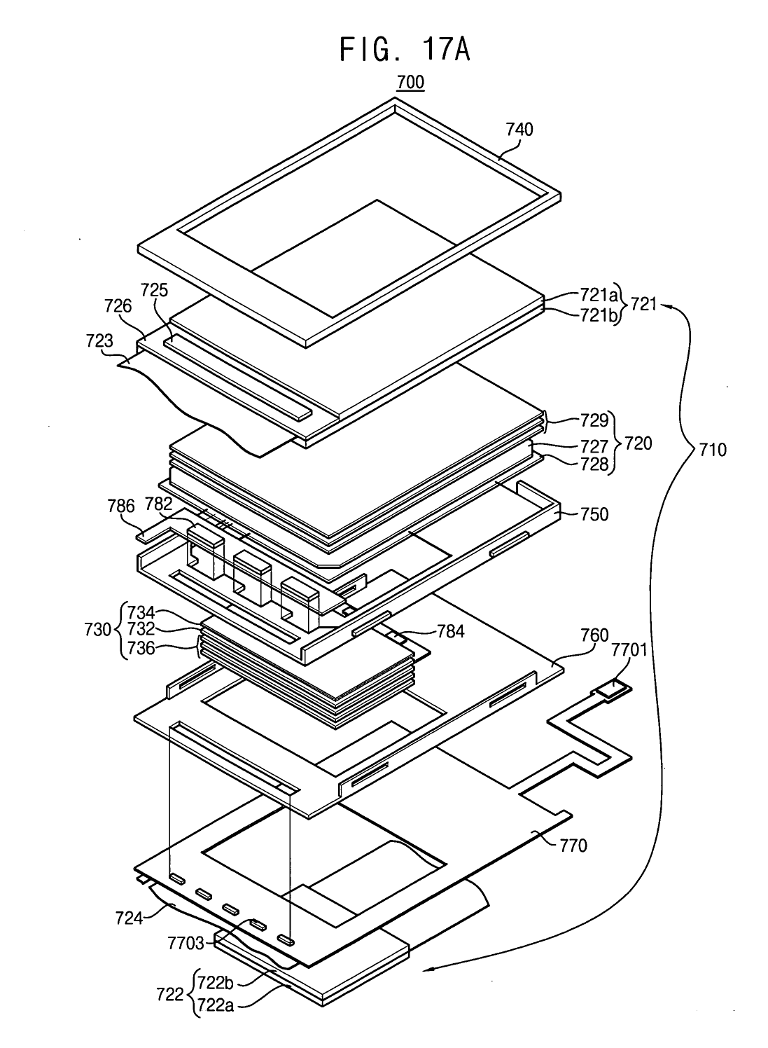

FIG. 15 is an exploded perspective view showing a liquid crystal display apparatus according to another exemplary embodiment of the present invention.

Referring to FIG. 15, a liquid crystal display apparatus 500 includes a lamp 530, a light control part 520 and a liquid crystal panel 560. The light control part 520 has a light guide plate 522, a reflecting sheet 521 and a reversed prism film 523. Light generated from the lamp 530 is supplied to the reversed prism film 523 by the light guide plate 522 and the reflecting sheet 521. The reversed prism film 523 diffuses and collects the light, and the liquid crystal panel 560 displays an image using the light emitted from the reversed prism film 523. The liquid crystal panel 560 includes a color filter substrate 562, a thin film transistor substrate 564, a source printed circuit board 570, a source driver 566 and a gate driver 568. The reflecting sheet 521 may have substantially the same structure as the optical film 40 of FIGS. 2 and 3 and includes the hollow particles 43 (refer to FIGS. 2 and 3) so as to improve diffusion and reflection characteristics of the reflecting sheet 521.

The lamp 530 may include a cold cathode fluorescent, a light emitting diode or an external electrode fluorescent.

The light guide plate 522 has a plurality of prisms that are formed on a reflection surface of the light guide plate 522 facing to the reflecting sheet 521. The prisms of the light guide plate 522 collect the light supplied to the light guide plate 522 such that the light collected by the prisms is outputted from an emitting surface of the light guide plate 522 in a substantially vertical direction with respect to the emitting surface. The reversed prism film 523 receives the light outputted from the light guide plate 522, and collects the light. Therefore, the light collected by the reversed prism film 523 is supplied to the liquid crystal panel 560.

The prisms of the reversed prism film 523 are formed on a surface facing the light guide plate 522 and extended in a direction substantially parallel with the longitudinal direction of the lamp. The prisms of the light guide plate 522 are extended in a direction substantially perpendicular to a longitudinal direction of the lamp 530. Thus, the prisms of the reversed prism film 523 traverse the prisms of the light guide plate 522.

FIG. 16 is an exploded perspective view showing a liquid crystal display apparatus according to another exemplary embodiment of the present invention.

Referring to FIG. 16, a liquid crystal display apparatus 600 includes a backlight assembly 200, a display unit 620 and a top chassis 630. The backlight assembly 200 generates light, and the display unit 620 displays images using the light from the backlight assembly 200. The top chassis 630 fixes the display unit 620 onto the backlight assembly 200.

In the present embodiment, the backlight assembly 200 has substantially the same structure as the backlight assembly 200 of FIG. 12, and thus any further repetitive descriptions of the same elements will be omitted.

The receiving container 260 includes a bottom chassis 262 and a mold frame 264. The mold frame 264 has four sidewalls to guide a receiving position of the light source 210 and the light guide plate 220, and a bottom face of the mold frame is opened. The bottom chassis 262 has a bottom face and four sidewalls extended from the bottom face of the bottom chassis 262. The bottom chassis 262 is coupled to the mold frame 264 by a hook.

The reflecting sheet 240, the light source 210, the light guide plate 220 and the optical sheets 250 are sequentially received in the receiving container 260.

The display unit 620 is disposed on the backlight assembly 200 and displays images using the light outputted from the backlight assembly 200.

Particularly, the display unit 620 includes a liquid crystal panel 624, a driving device 626 and a flexible circuit part 628. The driving device 626 may be implemented with an IC chip.

The liquid crystal panel 624 has a first substrate, a second substrate and a liquid crystal layer (not shown). The second substrate is coupled to the first substrate and the liquid crystal layer is disposed between the first substrate and the second substrate.

The driving device 626 is mounted on the first substrate and provides a driving signal to a data line and a gate line. The driving device 626 may have, for example, two chips including a chip for the data line and a chip for the gate line. In alternative embodiments, the driving device 626 may have one-integrated chip for the data line and the gate line. The driving device 626 is mounted on the first substrate via a chip on glass (COG) process.

Also, the flexible circuit part 628 is attached to the first substrate and provides a control signal to the driving device 626. The flexible circuit part 628 is electrically connected to the first substrate by an anisotropic conductive film. A timing controller to control a timing of the driving signal and a memory to store a data signal are mounted on the flexible circuit part 628.

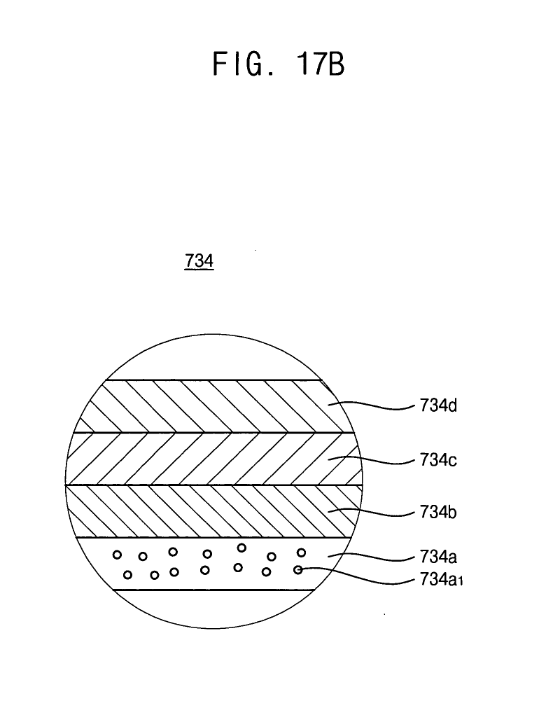

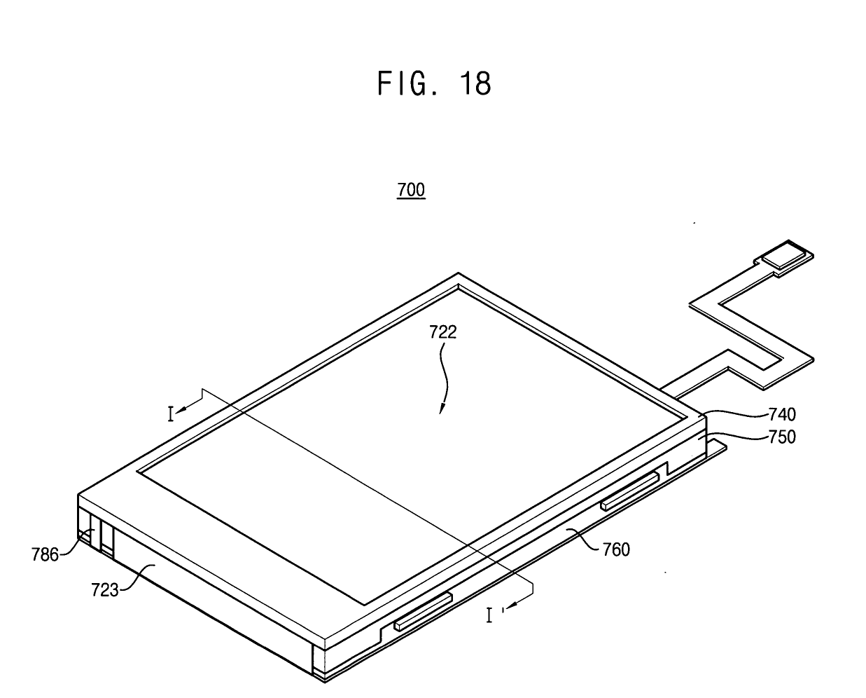

FIG. 17A is an exploded perspective view showing a liquid crystal display apparatus according to another exemplary embodiment of the present invention.

FIG. 17B is a partially enlarged view of the reflecting sheet shown in FIG. 17A.

Referring to FIGS. 17A and 17B, a liquid crystal display apparatus 700 includes a display panel assembly 710, a first backlight assembly 720, a second backlight assembly 730, a top chassis 740, a mold frame 750 and a bottom chassis 760. The first and second backlight assemblies 720 and 730 generate light.

The display panel assembly 710 includes a main display panel 721, a sub display panel 722, a first printed circuit board 723, a second printed circuit board 724 and an integrated circuit chip 725.

The main display panel 721 has a larger size than the sub display panel 722. Also, the liquid crystal display apparatus 700 may be used for a folder type portable phone. In the folder type portable phone, the main display panel 721 is disposed inside the folder type portable phone and the sub display panel 722 is disposed outside the folder type portable phone. Therefore, when the folder type portable phone is closed, the sub display panel 722 displays a relatively small amount of information on its screen due to its smaller size. Likewise, when the folder type portable phone is opened, the main display panel 721 displays a relatively large amount of information on its screen due to its larger size.

Since the sub display panel 722 has a smaller size than the main display panel 721, the second backlight assembly 730 has a smaller size than the first backlight assembly 720.

In FIGS. 17A and 17B, the liquid crystal display apparatus 700 having the main display panel 721 and the sub display panel 722 opposite to the main display panel 721 have been described, however, the present invention should not be limited to this exemplary embodiment and a structure and a composition of the liquid crystal display apparatus 700 may be varied.

Further, although the liquid crystal display apparatus 700 having two display panels 721 and 722 has been described in FIGS. 17A and 17B, the present invention should not be limited to this exemplary embodiment. That is, the liquid crystal display apparatus 700 may have two or more display panels. Although the liquid crystal display apparatus 700 having two liquid crystal display panels has been described in FIGS. 17A and 17B, the present invention should not be limited to this exemplary embodiment. That is, the liquid crystal display apparatus 700 may have at least one liquid crystal display panel and a light receiving type display panel.

Hereinafter, an internal structure of the main display panel 721 will be described. The sub display panel 722 has a same structure as the main display panel 721, and thus descriptions of the sub display panel 722 will be omitted.

The main display panel 721 includes a thin film transistor substrate 721b having a transparent glass substrate on which a plurality of thin film transistors are formed in a matrix shape. The thin film transistor includes a source electrode, a gate electrode and a drain electrode. The source electrode is electrically connected to a data line, and the gate electrode is electrically connected to a gate line. The drain electrode is electrically connected to a pixel electrode. The pixel electrode includes a transparent conductive material such as indium tin oxide.

A main printed circuit board 770 is electrically connected to the data line and gate line. When an electrical signal from the main printed circuit board 770 is applied to the data line and the gate line, the thin film transistor is turned on or off in response to the electrical signal supplied to the source and gate electrodes via the data and gate lines. Therefore, the drain electrode of the thin film transistor outputs an electrical signal required for forming a pixel.

The main display panel 721 further includes a color filter substrate 721a facing the thin film transistor substrate 721b. The color filter substrate 721a is disposed over the thin film transistor substrate 721b. The color filter substrate 721a has a RGB pixel and a common electrode. The RGB pixel is formed on a substrate by a thin film process and expresses a predetermined color using light passed through the RGB pixel. The common electrode is formed on the RGB pixel and includes indium tin oxide. When the thin film transistor is turned on in response to the electrical signal that is applied to the source and gate electrodes, an electric field is formed between the pixel electrode and the common electrode. An alignment angle of liquid crystals that are injected into a space between the thin film transistor substrate 721b and the color filter substrate 721a is varied by the electric field. Therefore, a light transmittance of the liquid crystals is varied in accordance with the alignment angle of liquid crystals, so that the main display panel 721 may display a desired pixel. Two polarizing plates (not shown) are attached to outer surfaces of the thin film transistor substrate 721b and the color filter substrate 721a, respectively.

The sub display panel 722 also includes a color filter substrate 722a and a thin film transistor substrate 722b, which have substantially the same configuration as those of the main display panel 721.

The integrated circuit chip 725 provides the driving signal and the timing signal to the gate line and the data line so as to control an alignment angle and an alignment time of the liquid crystal. The integrated circuit chip 725 is attached to the thin film transistor substrate 721b and surrounded by a passivation layer 726. The integrated circuit chip 725 generates a data signal and a data signal to drive the main display panel 721 and a plurality of timing signals to timely provide the data signal and the gate signal to the main display panel 721. The gate signal and the data signal are applied to the gate line and the data line, respectively. The second printed circuit board 724 receives the driving signal from the main display panel 721 and provides the driving signal to the sub display panel 722 via another integrated circuit chip.

A plurality of resistances 7703 is mounted on the main printed circuit board 770 that provides a signal to the first printed circuit board 723, and a connecter 7701 of the folder type portable phone is mounted on the main printed circuit board 770. The first printed circuit board 723 electrically connects the main display panel 721 with the main printed circuit board 770. In FIGS. 17A and 17B, the first printed circuit board 723 may be divided into two portions, but the two portions of the first printed circuit board 723 are electrically connected to each other.

The first backlight assembly 720 and the second backlight assembly 730 are disposed between the main display panel 721 and the sub display panel 722. The first backlight assembly 720 and the second backlight assembly 730 provide the light to the main display panel 721 and the sub display panel 722, respectively.

The mold frame 750 receives the first and second backlight assemblies 720 and 730. The second backlight assembly 730 has a smaller size than the first backlight assembly 720 and a substantially same structure as the first backlight assembly 720. Although the liquid crystal display apparatus 700 having two backlight assemblies 720 and 730 has been described in FIGS. 17A and 17B, however, the present invention should not be limited to this exemplary embodiment. That is, the liquid crystal display apparatus 700 may have one backlight assembly to provide the light to the main and sub display panels 721 and 722.

The first backlight assembly 720 includes a first light source 782, a first light guide plate 727, a first reflecting sheet 728 and a first optical sheet 729. The first light source 782 generates the light, and the first light guide plate 727 guides the light toward the main display panel 721. The first reflecting sheet 728 reflects the light to the first light guide plate 727, and the first optical sheet 729 improves brightness of the light and provides the light having an improved brightness to the main display panel 721.

In FIGS. 17A and 17B, the first light source 782 includes light emitting diodes that are mounted on a substrate 786, but the first light source 782 may include a lamp or a line light source and a surface light source using the light emitting diodes. Also, the first light source 782 includes three light emitting diodes in FIGS. 17A and 17B, but the number of the light emitting diodes may be varied.

The substrate 786 is electrically connected to the main printed circuit board 770 and receives a light control signal from the printed circuit board 770. The first light source 782 that is mounted on the substrate 786 operates in response to the light control signal. The second backlight assembly 730 having a substantially same structure as the first backlight assembly 720 includes a second light source 784, a second light guide plate 732, a second reflecting sheet 734 and a second optical sheet 736.

The mold frame 750 receives the first light source 782 mounted on the substrate 786, the display panel assembly 710, and the first and second backlight assemblies 720 and 730.

The top chassis 740 is disposed over the display panel assembly 710, and the bottom chassis 760 is disposed under the display panel assembly 710. The top chassis 740 and the bottom chassis 760 are coupled to a side surface of the mold frame 750. The main printed circuit board 770 covers a bottom surface of the bottom chassis 760 in which the mold frame 750 is received.

In the liquid crystal display apparatus 700 according to an exemplary embodiment of the present invention, at least one of the first and second reflecting sheets 728 and 734 may include a hybrid-type reflecting sheet. The hybrid-type reflecting sheet has a multi-layer structure and reflects most of light supplied to the hybrid-type reflecting sheet due to inherent characteristics of the multi-layer. Especially, the hybrid-type reflecting sheet is employed in lieu of a blocking sheet, so that the liquid crystal display apparatus 700 does not need to have the blocking sheet. Therefore, the number of elements and a thickness of the liquid crystal display apparatus 700 may be reduced, thus characteristics of the liquid crystal display apparatus 700, such as thickness, weight, size or strength, may be improved.

In the liquid crystal display apparatus of FIGS. 17A and 17B, the first reflecting sheet 728 includes an enhanced specular reflecting (ESR) sheet and the second reflecting sheet 734 includes the hybrid-type reflecting sheet. However, the first and second reflecting sheets 728 and 734 according to the present invention should not be limited to this exemplary embodiment. That is, the first reflecting sheet 728 may include the hybrid-type reflecting sheet and the second reflecting sheet 734 may include the enhanced specular reflecting sheet. Also, the first and second reflecting sheets 728 and 734 may include the hybrid-type reflecting sheet.

In liquid crystal display apparatus 700, the second reflecting sheet 734 is inverted, so that a rear surface and a front surface of the second reflecting sheet 734 are reversed. Hereinafter, a structure of the second reflecting sheet 734 viewed from an upper side of liquid crystal display apparatus 700 will be described with reference to FIG. 17B.

The second reflecting sheet includes a base layer 734b and a resin layer 743a disposed on the base layer 734b. The resin layer 743a has a plurality of hollow particles 734a1 added into the resin layer 743a. The second reflecting sheet 734 may further include another layer on occasion. Especially, the second reflecting sheet 734 may further include a light reflecting metal layer 734c disposed directly under the base layer and a passivation layer 734d disposed directly under the light reflecting metal layer 734c.

The resin layer 734a may include polyurethane. The hollow particles 734a1 may include a transparent resin layer and an inner space of the hollow particles 734a1 may be empty. A portion of the light supplied to the resin layer 734a is reflected by a surface of the hollow particles 734a1 and a remaining portion of the light is supplied to the inner space of the hollow particles 734a1. Since the resin layer 734a has a refractive index different from the transparent resin layer of the hollow particles 734a1, the light supplied to the resin layer 734a is diffusely reflected. Especially, since the transparent resin layer of the hollow particles 734a1 has a refractive index different from the inner space, the light supplied to the resin layer 734a is diffusely reflected. The inner space of the hollow particles 734a1 is filled with an air, so that the inner space has a refractive index of about 1.

The hollow particles 734a1 have, for example, a cylindrical shape or a spherical shape such that the light is diffusely reflected by the hollow particles 734a1. The hollow particles 734a1 have a diameter corresponding to a wavelength of the light supplied to the resin layer 734a. When assuming that the ‘λ’ is a wavelength of green light having a wavelength of about 550 nm, the hollow particles 734a1 have a diameter of about 2.9λ/2 to about 3.1λ/2 or substantially 3.0λ/2. Particularly, when the red light has a wavelength of about 650 nm, the hollow particles 734a1 have a diameter of about 97.5 angstroms. When the green light has a wavelength of about 550 nm, the hollow particles 734a1 have a diameter of about 82.5 angstroms. When the blue light has a wavelength of about 450 nm, the hollow particles 734a1 have a diameter of about 67.5 angstroms. An epidermis of the hollow particles 743a1 has a thickness of about 0.49λ to about 0.51λ or substantially 0.5λ, thereby improving an efficiency of the diffusely reflecting.

The base layer 734b includes a resin, such as a polyethylene terephthalate-based resin. The base layer 734b is disposed directly under the resin layer 734a and supports the resin layer 734a. The base layer 734b receives light passing through the resin layer 734a.

The light reflecting metal layer 734c is disposed directly under the base layer 734b and reflects light transmitted through the base layer 734b toward the base layer 734b. The light reflecting metal layer 734c includes a material having a high reflectance, such as silver (Ag) or aluminum (Al). Therefore, the second reflecting sheet 734 reflects most of the light supplied to the second reflecting sheet 734, thereby reducing light loss of the second reflecting sheet 734. The passivation layer 734d is disposed directly under the light reflecting metal layer 734c and may prevent the split of the second reflecting sheet 734.

FIG. 18 is a combined perspective view showing a liquid crystal display apparatus of FIG. 17A.

Referring to FIG. 18, the liquid crystal display apparatus 700 has a reflecting sheet according to the present invention, thereby improving brightness of light and displaying a clear image. Also, the liquid crystal display apparatus 700 may prevent a leakage of the light, so that the light may be supplied to only one of the main and sub display panels on which an image is displayed.

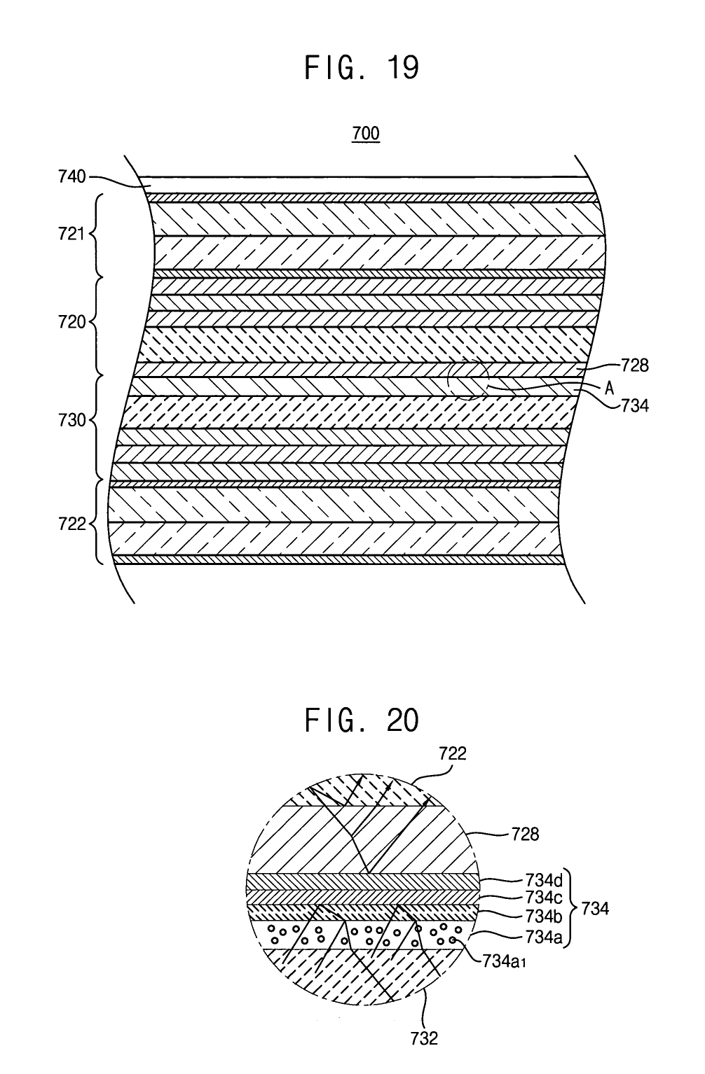

FIG. 19 is a cross-sectional view taken along line I-I′ in FIG. 18. FIG. 20 is an enlarged view showing portion “A” of FIG. 19. FIG. 19 represents the main display panel 721, the first backlight assembly 720, the second backlight assembly 730 and the sub display panel 722 that are sequentially stacked, and FIG. 20 represents a reflecting path of the light outputted from the light source.

Referring to FIGS. 19 and 20, the first reflecting sheet 728 of the first backlight assembly 720 makes contact with the second reflecting sheet 734 of the second backlight assembly 730. The second reflecting sheet 734 acts as a blocking sheet, so that the light passing through the first reflecting sheet 728 after outputting from the first light source is reflected by the second reflecting sheet 734. Therefore, the liquid crystal display apparatus does not need a separate blocking sheet.

As shown in FIG. 20, the light outputted from the second light source is supplied to the second reflecting sheet 734 via the resin layer 734a of the second reflecting sheet 734. The light supplied to the second reflecting sheet 734 is diffusely reflected by the resin layer 734a. Since the hollow particles 734a1 are added into the resin layer 734a, the resin layer 734a may diffusely reflect the light with efficiency. Next, the light passing through the resin layer 734a is reflected from the light reflecting metal layer 734c. Therefore, the second reflecting sheet 734 may reflect most of the light supplied to the second reflecting sheet 734, thereby reducing the light loss of the second reflecting sheet 734.

As described the above, the optical film includes the polyurethane resin and the hollow particles that are added into the polyurethane and coated on the metal deposited film, thereby improving diffusivity and reflectivity of the optical film. The hollow particles include a transparent resin, and an inner space in the hollow particles is empty. Therefore, the hollow particles may reflect the light due to the refractive index difference between the transparent resin and the inner space.

Also, the reflecting sheet of the liquid crystal display apparatus includes the base layer and the resin layer into which the hollow particles are added, thereby diffusely reflecting the light supplied to the hollow particles with efficiency.

The reflecting sheet further includes the metal layer to reflect the light passing through the resin layer and the passivation layer. Therefore, the light loss of the reflecting sheet may be reduced, and durableness of the reflecting sheet may be improved.

In the backlight assembly according to present invention, the light from the light source is firstly incident into the resin layer. Thus, the brightness of the light emitted from the backlight assembly may be enhanced, and the liquid crystal display apparatus may display a clear image.

Also, the epidermis of the hollow particles includes a transparent resin having the refractive index different from the inner space of the hollow particles, such that the reflecting sheet may diffusely reflect the light supplied to the hollow particles with efficiency.

The resin layer has the refractive index different from the transparent resin, thereby improving diffusely-reflected efficiency of the reflecting sheet.

Also, the reflecting sheet may act as the blocking sheet, thus characteristics of the liquid crystal display apparatus, such as thickness, weight, size and strength may be improved.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. An optical film comprising:
a base layer;
a resin layer disposed on the base layer; and
a plurality of hollow particles disposed in the resin layer.

2. The optical film of claim 1, wherein the resin layer comprises a polyurethane-based resin.

3. The optical film of claim 1, wherein the hollow particles have a diameter determined by a wavelength of light supplied to the optical film.

4. The optical film of claim 1, wherein the hollow particles have a diameter of substantially 3.0×λ/2, and ‘λ’ denotes a wavelength of light supplied to the optical film.

5. The optical film of claim 4, wherein the hollow particles have a diameter of about 65.2 angstroms to about 100.7 angstroms.

6. The optical film of claim 1, wherein the hollow particles include an epidermis having a thickness of substantially 0.5λ, here ‘λ’ denotes a wavelength of light supplied to the optical film.

7. The optical film of claim 6, wherein the epidermis thickness of the hollow particles is from about 22 angstroms to about 33.1 angstroms.

8. The optical film of claim 1, wherein the base layer comprises a polyethylene terephthalate-based resin.

9. The optical film of claim 1, further comprising a metal layer disposed on the base layer, the metal layer being disposed on an opposite side of the resin layer with respect to the base layer.

10. The optical film of claim 9, further comprising a passivation layer disposed on the metal layer, the passivation layer being disposed on an opposite side of the base layer with respect to the metal layer.

11. The optical film of claim 1, wherein the hollow particles comprise an epidermis that defines an inner space of a hollow particle, the epidermis comprises a first resin having a refractive index different from a refractive index of the inner space, and the hollow particles reflect light supplied to the hollow particles due to a refractive index difference between the first resin and the inner space.

12. The optical film of claim 11, the resin layer comprises a second resin, and the resin layer reflects light supplied to the resin layer due to a refractive index difference between the first resin and the second resin.

13. The optical film of claim 11, wherein the first resin comprises a transparent material.

14. The optical film of claim 1, wherein the hollow particles comprise an epidermis that defines an inner space of a hollow particle, the epidermis comprises a first resin having a refractive index different from a refractive index of the inner space, and the hollow particles transmit light supplied to the hollow particles due to the refractive index difference between the first resin and the inner space.

15. The optical film of claim 1, wherein the hollow particles comprise an epidermis having a ball shape and diffuse light supplied to the hollow particles via the epidermis.

16. The optical film of claim 1, wherein an outer surface of the hollow particles reflects and transmits light supplied to the hollow particles.

17. The optical film of claim 1, wherein an inner surface of the hollow particles reflects and transmits light supplied to the hollow particles.

18. The optical film of claim 1, wherein the resin layer has a substantially same material as the hollow particles.

19. The optical film of claim 1, wherein the resin layer has a substantially same refractive index as the hollow particles.

20. The optical film of claim 1, wherein the resin layer has a refractive index different from a refractive index of the hollow particles.

21. A backlight assembly comprising:
a lamp generating light; and
an optical film reflecting the light from the lamp, the optical film comprising a base layer, a resin layer disposed on the base layer, and a plurality of hollow particles disposed in the resin layer.

22. The backlight assembly of claim 21, further comprising a light guide plate disposed adjacent to the lamp and the optical film, and the light guide plate guides a path of the light generated from the lamp and the light reflected by the optical film.

23. The backlight assembly of claim 22, wherein the hollow particles each include an epidermis that defines an inner space of a hollow particle, the epidermis includes a resin having a refractive index different from a refractive index of the inner space, and the hollow particles reflect or transmit light supplied to the hollow particles due to a refractive index difference between the resin and the inner space.

24. A display apparatus comprising:
a light source to generating light;
a liquid crystal display panel displaying images using a potential difference that is applied to a liquid crystal layer; and
an optical film diffusely reflecting the light from the lamp toward the liquid crystal display panel, the optical film comprising a base layer, a resin layer disposed on the base layer, and a plurality of hollow particles disposed in the resin layer.

25. A display apparatus comprising:
at least two display panels displaying images;
at least one backlight assembly supplying light to the display panels, the backlight assembly comprising a reflecting sheet to reflect the light, the reflecting sheet comprising a base layer, a resin layer disposed on the base layer, and a plurality of hollow particles disposed in the resin layer.

26. The display apparatus of claim 25, wherein the reflecting sheet further comprises:
a light reflecting layer disposed on the base layer, the light reflecting layer being disposed on an opposite side of the resin layer with respect to the base layer; and
a passivation layer disposed on the light reflecting layer, the passivation layer being disposed on an opposite side of the base layer with respect to the light reflecting layer.

27. The display apparatus of claim 26, wherein the backlight assembly further comprises a light source to generate the light, and the light is incident into the resin layer and reflected by the light reflecting layer.

28. The display apparatus of claim 26, wherein the light reflecting layer is a metal layer.

29. The display apparatus of claim 25, wherein the hollow particles include an epidermis having a transparent resin.

30. The display apparatus of claim 29, wherein the resin layer has a refractive index different from a refractive index of the epidermis of the hollow particles.

31. The display apparatus of claim 25, wherein the base layer comprises polyethylene terephthalate, and the resin layer comprises polyurethane.

32. The display apparatus of claim 25, wherein the at least one backlight assembly comprises a first backlight assembly and a second backlight assembly having a size smaller than the first backlight assembly, the reflecting sheet comprises a first reflecting sheet of the first backlight assembly and a second reflecting sheet of the second backlight assembly, and the first reflecting sheet makes contact with the second reflecting sheet.

33. The display apparatus of claim 25, wherein the at least two display panels comprise at least one liquid crystal display panel.

34. The display apparatus of claim 25, wherein the at least two display panels and the at least one backlight assembly are configured in a mobile phone.
